(19) United States
(12) Patent Application Publication
(10) Pub. No.: US 2006/0022737 A1
(43) Pub. Date: Feb. 2, 2006

(54) Device for the regulated delay of a clock signal

(75) Inventors: Peter Gregorius, Munchen (DE); Andreas Jakobs, Munchen (DE)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 11/194,510

(22) Filed: Aug. 1, 2005

(30) Foreign Application Priority Data
Jul. 30, 2004 (DE) 10 2004 037 164.4

(51) Int. Cl. H03H 11/26

(52) U.S. Cl. 327/276

(57) ABSTRACT

A device for the regulated delay of a clock signal is proposed, which comprises a delay means in order to generate a delayed clock signal, and comparison means for the phase comparison of the delayed clock signal with a reference clock signal. The reference clock signal is in this connection preferably formed by the clock signal or is derived therefrom. On the basis of a comparison signal generated by the comparison means, a digital control signal is generated for controlling the delay means. The comparison means are configured so as to generate the comparison signal as a digitally coded signal that has a pulse duty ratio and a frequency that are determined by a further clock signal that is generated independently of the first clock signal, and that preferably has twice the frequency of the first clock signal.

The present invention relates to a device for the regulated delay of a clock signal. The device is suitable in particular for use in an interface for memory applications.

With physical interfaces for memory applications, for example for so-called DDR memories, various types of signals are used in order to transfer data from and to the memory and to control the memory. Such data include specifically control clock signals, data signals and sampling signals, so-called strobe signals, as well as command and address signals. An adjustment of the phase relationships of these signals to one another and relative to an external clock signal is necessary for an effective communication between the memory and the interface.

To adjust the desired phase relationships between the signals it is conventional to employ so-called delay locked loops. These are delay control loops that compare a clock signal with a delayed clock signal and regulate the delay in such a way that the phase relationship of the clock signal and of the delayed clock signal adopts a fixed value. A delay locked loop may in this connection specifically delay in a regulated manner also clock-type signals that do not exhibit a complete periodicity, i.e. that are only intermittently periodic.

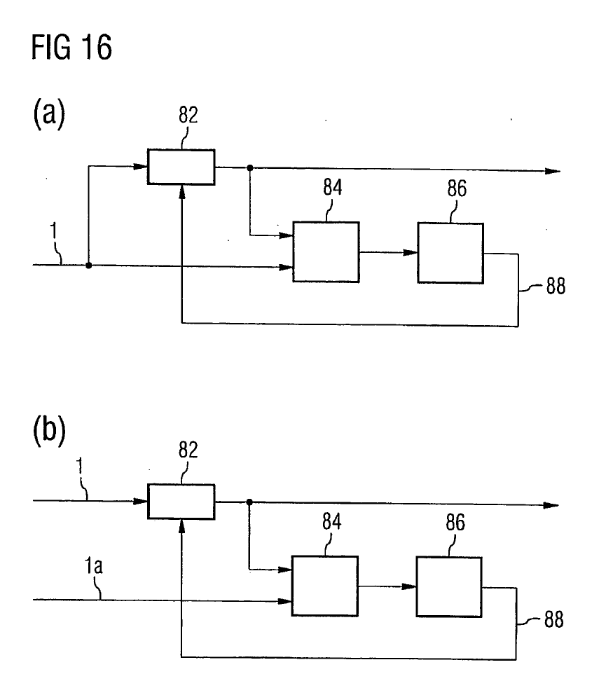

Examples of such delay loops are illustrated in FIGS. 16(a) and (b). The delay locked loop of FIG. 16(a) receives as input signal a clock signal 1. The clock signal is delayed by means of a delay means 82 for a specific duration that can be adjusted by means of a control signal 88. The output signal of the delay means 82 thus forms a delayed clock signal. The delayed clock signal is compared by comparison means 84 with the non-delayed clock signal 1 as regards the relative phase relation (phase angle). An output signal of the comparison means 84, which is generated on the basis of the comparison of the clock signal 1 with the delayed clock signal, is fed via a loop filter 86 as the control signal 88 to the delay means 82.

An alternative form of delay locked loop is illustrated in FIG. 16(b). This corresponds as regards the delay means 82, the comparison means 84 and the loop filter 86 to the delay locked loop already described above on the basis of FIG. 16(a). The difference here however is that two clock signals 1, 1a are fed to the delay locked loop, the phase relationship of the signals being adjusted by the delay control loop. This is achieved by the fact that the clock signal 1 is delayed by means of the delay means 82 in order to generate the delayed clock signal, while the delayed clock signal is compared by means of the comparison means 84 with the clock signal 1a, which thus has the function of a reference clock signal. The difference between the delay locked loops of FIG. 16(a) and FIG. 16(b) consists in the fact that in one case the phase relationship is adjusted with respect to the non-delayed clock signal 1, whereas in the other case the phase relationship is adjusted with respect to a reference clock signal 1a. The reference clock signal 1a may for example be derived externally from the clock signal 1.

As a rule, with memory interfaces it is necessary that not only a specific phase relationship is adjusted, but that for the different signals in each case the phase relation can also be adjusted individually. In this connection it is known to configure a device for the regulated delay of clock signals according to the so-called master-slave principle. At the same time it is conventional to use as delay means a delay chain with a plurality of delay stages. The delay of the delay means is first of all regulated in a master delay loop in such a way that a fixed phase relationship exists between the output signal of the delay means and the non-delayed clock signal or the reference clock signal. The actual generation of the delayed clock signals is however carried out by slave delay loops, which are constructed identically to the master delay loop but do not have their own control loop. The control signal of the master delay loop is then used as control signal for the delay means of the slave delay loop. A delayed output clock signal is generated by tapping, via a multiplexer, signals from the individual delay stages of the delay means. The delayed clock signals tapped in this way normally correspond to a fixed fraction of the delay adjusted by means of the master delay loop. In this way it is possible with the slave delay loops to select individually the desired phase relationship between the clock signal or reference clock signal and the respective delayed signal. In addition it is possible to localise flexibly the generation of delayed clock signals, for example in the vicinity of the use site of the delayed clock signal.

A general problem with delay locked loops is however the fact that they react sensitively to errors in the pulse duty ratio, a so-called duty cycle distortion, which may occur both in the input-side clock signal as well as within the delay means. In addition it is necessary to use as input signal a clock signal with a high spectral purity and low noise.

Analogue as well as digital signals can be used as control signals for the delay means. In the case of analogue control signals there is however the problem of a high sensitivity to interference from internal or external sources of disturbance. In this case the result is undesired fluctuations or additional noise within the delay means. These problems also cannot be avoided by configuring the loop in differential circuit technology. The use of analogue control signals in an arrangement constructed according to the master-slave principle described above is particularly problematic. In this case, depending on the circumstances, the control signal has to be transmitted over relatively long distances by the slave delay loop. The result is an increased susceptibility to interference and noise.

In order to provide a digital control signal for the delay means, it is known to use simple binary phase detectors. Such a binary phase detector may for example be based on a D-flip-flop element, whose clock input is fed with the clock signal and whose data input is fed with the delayed clock signal. However, with such a simple binary phase detector there is the danger that the master delay loop will be adjusted to a multiple of the desired delay. An additional effort must therefore be expended in order to detect such a false adjustment and if necessary to reset the delay regulation. In this case the interface would not be operable until the delay loop had been readjusted.

In view of the problems described above, the object of the present invention is to provide a device for the regulated delay of a clock signal that avoids these problems, that is robust with respect to the interferences described above, and that can be realised with a small effort and expenditure.

This object is achieved by a device according to claim 1. The dependent claims define preferred and advantageous embodiments of the invention.

According to the present invention a digital signal processing is provided. The device according to the invention for the regulated delay of a clock signal comprises delay means that are configured so as to delay a clock signal by a specific duration in order to generate a delayed clock signal. In addition comparison means are provided in order to compare the delayed clock signal as regards its phase with a reference clock signal. The reference clock signal may in particular be the non-delayed clock signal itself. It may however also be a clock signal derived from the clock signal, that has the same frequency but a different phase.

The comparison means are configured so as first of all to generate a comparison signal, depending on the comparison of the delayed clock signal with the reference clock signal, in which the delay means are configured so as to determine the duration by which the clock signal is delayed, depending on a control signal that is generated depending on the comparison signal.

In accordance with the invention it is provided for that a further clock signal, which is generated independently of the clock signal and reference clock signal, is fed to the comparison means. The comparison means are in this connection configured in such a way that they generate the control signal as a signal comprising a sequence of pulses, whose pulse duty ratio and/or whose fundamental frequency is defined by the further clock signal. As a result the comparison signal and the generated control signal based thereon are insensitive to disturbances of the clock signal or reference clock signal. The further clock signal forms in principle an independent control clock for the digital components of the comparison means. In particular no fixed phase relationship between the further clock signal and the clock signal or the reference clock signal is necessary, i.e. the further clock signal is a clock signal that is asynchronous with respect to the other clock signals. This approach improves in particular the sensitivity of the arrangement to errors in the pulse duty ratio of the clock signal or reference clock signal. Furthermore a digitally coded signal is formed as output signal of the comparison means, which constitute a digital phase detector, whereby it is possible to configure digitally further components of the delay control loop, for example a loop filter or the control of the delay means. Overall a simplified construction is achieved and the sensitivity to interferences is reduced still further.

The further clock signal is preferably provided by means of a phase locked loop and its frequency is a multiple of the frequency of the clock signal or reference clock signal. Preferably the frequency of the further clock signal is twice the frequency of the clock signal or reference clock signal. The result of this is that, on comparing the delayed clock signal with the reference clock signal a digital sampling can be carried out with sufficient accuracy. Alternatively it is also possible to generate the further clock signal with initially the same frequency as the clock signal or reference clock signal, and to provide in addition frequency multiplication means for multiplying the frequency of the further clock signal.

According to a preferred embodiment of implementation the comparison means comprise interconnection means to which the delayed clock signal and the reference clock signal are fed, wherein an output signal of the interconnection means is determined by the relative delay of the clock signal with respect to the reference clock signal. The interconnection means may in this connection be specifically based on a logic interconnection of the delayed clock signal with the reference clock signal, for example an AND interconnection. In this way it is possible to generate as output signal of the interconnection means a pulse-width modulated signal whose pulse width is determined by the relative delay of the delayed clock signal with respect to the reference clock signal. In this connection the output signal of the interconnection means is sampled by sampling means that are controlled by the further clock signal.

For the sampling of the pulse-width modulated output signal of the interconnection means, the sampling means preferably include a first flip-flop element whose input is supplied with the pulse-width modulated signal, and a second flip-flop element whose input is supplied with the output signal of the first flip-flop element. In this connection the first flip-flop element changes its state depending on the value of the further clock signal, i.e. is formed for example by a latch-flip-flop. The second flip-flop element changes its state however at an edge of the further clock signal, i.e. is formed for example by a D-flip-flop. Such an arrangement enables a pulse-width modulated signal to be converted in an advantageous way into a digitally coded signal with a fixed frequency and a defined pulse duty ratio that are determined by the further clock signal.

The delay means according to the invention preferably include a plurality of delay stages that are arranged in series. In this way a correspondingly delayed clock signal can be tapped at the output at each of the delay stages. Preferably each of the delay stages delays its input signal by an identical duration. In this way a delay is produced for the delayed clock signals that can be tapped at the respective delay stages, that is a multiple of the delay of an individual delay stage. The overall delay is thus divided into equal fractions and, if the delay loop is locked, a correspondingly fixed phase relation with respect to the reference clock signal is also produced for each of the delayed clock signals that can be tapped at the outputs of the delay stages. For example, for three delay stages that in each case produce a delay of one-eighth of the cycle duration of the clock signal, a relative phase relation of 45°, 90° and 135° would be obtained for the delayed clock signals that can be tapped at the corresponding outputs of the delay stages.

The delayed clock signal is fed to the comparison means, preferably in the form of subsignals that are tapped in each case at the output of the one of the delay stages. This means that the delayed clock signal consists of a plurality of subsignals which, compared to the clock signal, have a delay that in each case corresponds to a multiple of a unit delay.

In the case of a clock signal delayed in three stages, the interconnection means preferably comprise a first and a second AND interconnection means, in which the inputs of the first AND interconnection means are supplied with the reference clock signal and with a first and a second subsignal of the delayed clock signal, and wherein the inputs of the second AND interconnection means are supplied with the inverted reference clock signal as well as with the second clock signal and a third subsignal of the delayed clock signal. In this way a pulse-width modulated signal, whose pulse width varies between zero and the pulse width of the clock signal and reference clock signal, is in each case obtained as output signal of the AND interconnection means. In the case where the delay of the individual subsignals of the delayed clock signal corresponds in each case to a phase shift of 45°, 90° and 135° with respect to the reference clock signal, the pulse width of the output signal of the AND interconnection means is half the pulse width of the clock signal and of the reference clock signal.

It is particularly advantageous for the generation of a pulse-width modulated signal to use the AND interconnection means to which subsignals of the delayed clock signal are fed as input signals, in which the subsignals are delayed with respect to the reference clock signal in each case by a multiple of the unit delay of a delay stage. The number of subsignals is however not restricted to three, and it is also possible to use a larger number of subsignals, the number of subsignals preferably being an odd number and greater than three. If therefore the delayed clock signal comprises 2n+1 subsignals, the first to the (n+1)th subsignal and the reference clock signal are fed to the first AND interconnection means, while the (n+1)th to the (2n+1)th subsignal and the inverted reference clock signal are fed to the second AND interconnection means. In general the pulse width of the output signal of the AND interconnection means would then be half the pulse width of the clock signal and reference clock signal if the unit delay of a delay stage corresponds to a phase shift of a correspondingly smaller fraction of a clock cycle. Thus, for example in the case of five subsignals, i.e. n=2, the pulse-width modulated signal would have half the pulse width of the clock signal or of the reference clock signal if the unit delay of a delay stage is a twelfth of the cycle duration of the clock signal and reference clock signal. In general this fraction is ¼(n+1).

With this arrangement the first AND interconnection means, to which the reference clock signal is fed, generates a pulse-width modulated output signal whose pulse width increases when the delay of the delayed clock signal decreases. The second AND interconnection means, to which the inverted reference clock signal is fed, generates a pulse-width modulated signal whose pulse width increases with the delay of the delayed clock signal. The output signals of the AND interconnection means are therefore ideally suitable for adjusting the delay of the delayed clock signal to a desired value with respect to the cycle duration of the reference clock signal or clock signal. It is therefore particularly advantageous according to the invention if the digitally coded control signal for the delay means is generated by sampling the output signals of the AND interconnection means.

A particular advantage of the comparison means described above is considered to be the fact that it avoids that the delay loop locks to a multiple of the cycle duration of the reference clock signal or clock signal. This is specifically ensured by the fact that in the phase comparison of the delayed clock signal with the reference clock signal, a plurality of subsignals are included that correspond in each case to a different fraction of the overall delay. This enables a regulation to be carried out that adjusts the delay of a delay stage to a predetermined fraction of the cycle duration of the reference clock signal or clock signal. With a multiplication of the delay of a delay stage this predetermined fraction could no longer be achieved, with the result that an incorrect adjustment is avoided.

The device according to the invention preferably includes further delay means, which are driven by the same control signal. In this way the arrangement can be configured according to the master-slave principle, in which the further delay means serve for the actual generation of the output clock signal and do not require their own control loop. By means of these further delay means it is possible to generate further delayed output clock signals, allowing for the generation of the output clock signals to take place in the vicinity of their place of use. The digitally coded control signal permits in this connection an interference-insensitive and reliable transmission of the control signal to the desired site. In addition it is possible to provide several further delay means that provide in each case different delays, i.e. different phase relationships with respect to the reference clock signal, for their output clock signal.

The further delay means are in this connection preferably configured identically to the delay means of the control loop and accordingly likewise preferably comprise several delay stages. The delayed output clock signal may then be tapped at the outputs of the delay stages. Depending on at which output the output clock signal is tapped, the delayed output clock signal has a different phase relationship with respect to the reference clock signal. The delay may be selected in the fractions of the cycle duration of the reference clock signal or clock signal that are adjusted by the control loop. The selection of the corresponding outputs preferably takes place by driving a multiplexer means so that the desired phase relationship can be flexibly adjusted. In addition interpolation means may also be provided, which by interpolation of at least two of the clock signals that can be tapped at the delay stages generate a delayed clock signal whose phase relationship has an intermediate value, so that it is also possible to adjust phase relationships for the output clock signal that have a phase relation between the values defined by the individual delay stages.

The device according to the invention is preferably configured for use in the generation and synchronisation of timing, sampling, data, command and address signals for memory devices and is provided for example as a component of a memory interface.

The present invention enables the sensitivity of a delay locked loop to be significantly reduced as regards errors in the pulse duty ratio. In particular, the control signal for the delay means generated according to the present invention enables simplified components to be used and increases the robustness of the device with regard to internal or external interferences.

The invention is explained in more detail hereinafter with the respect to a preferred embodiment and with reference to the accompanying drawings, in which:

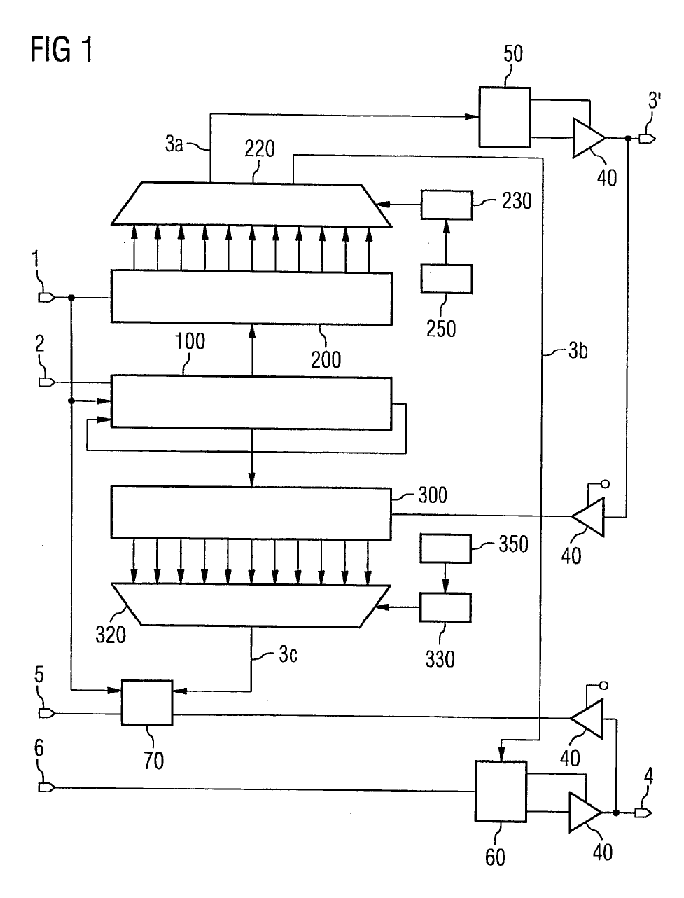

FIG. 1 shows diagrammatically a circuit block for the generation and synchronisation of data signals and sampling signals in a memory interface,

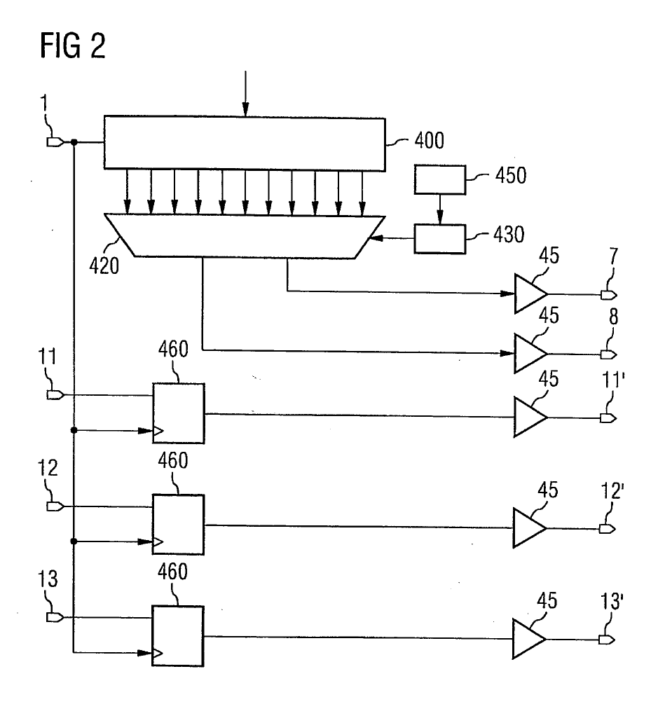

FIG. 2 shows diagrammatically a further circuit block for the generation and synchronisation of clock, command and address signals,

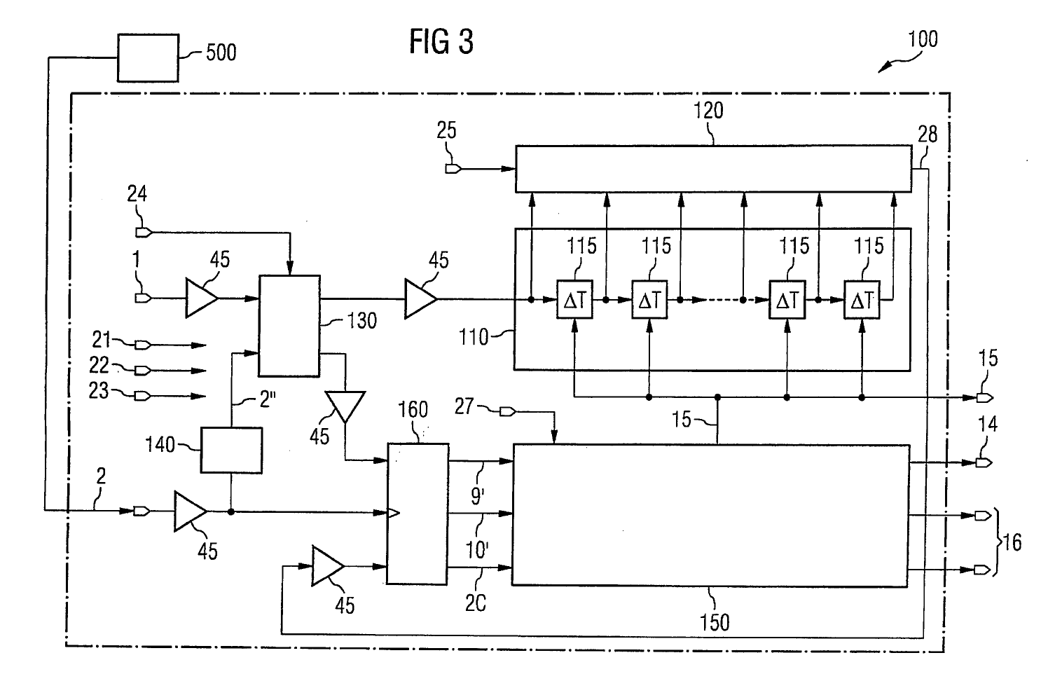

FIG. 3 shows the structure of a master delay control loop according to a first embodiment,

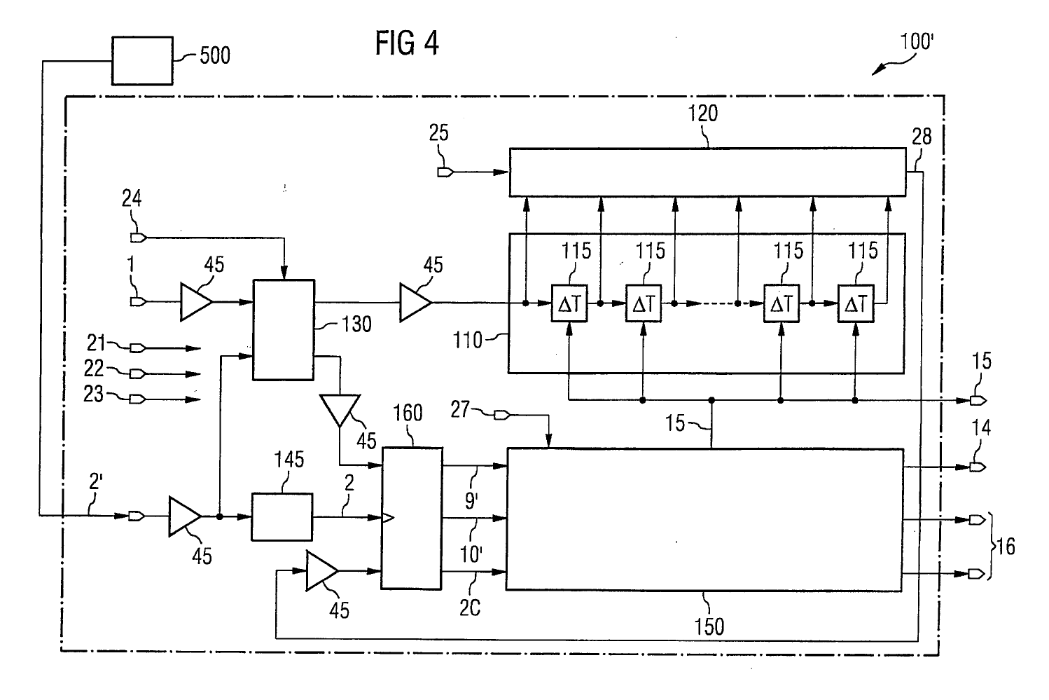

FIG. 4 shows the structure of a master delay control loop according to a second embodiment,

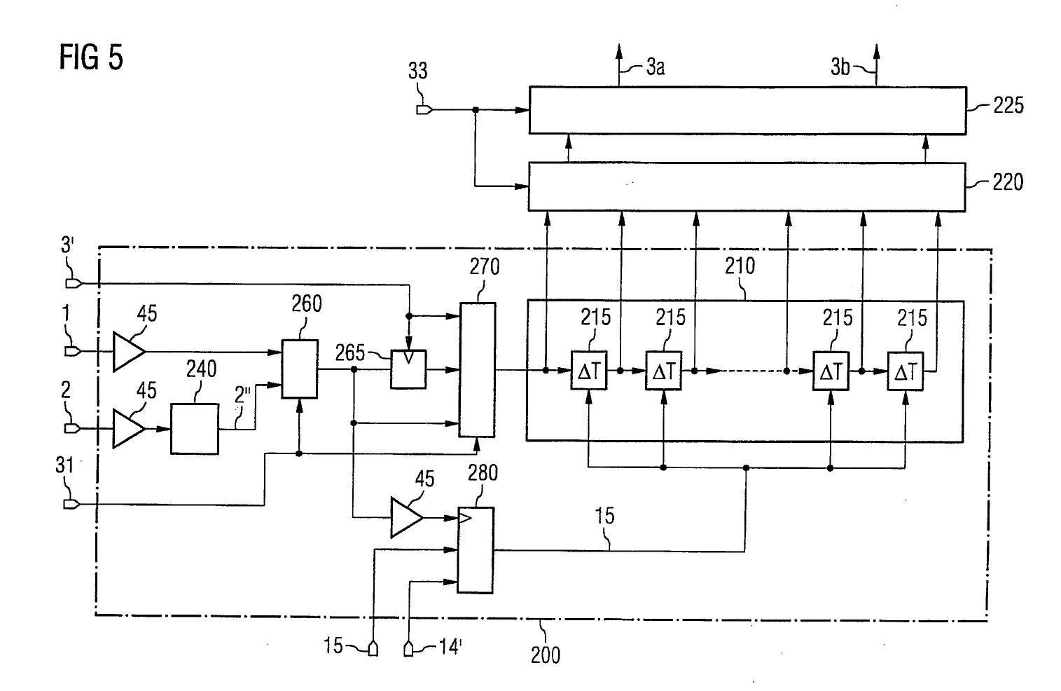

FIG. 5 shows the structure of a slave delay control loop,

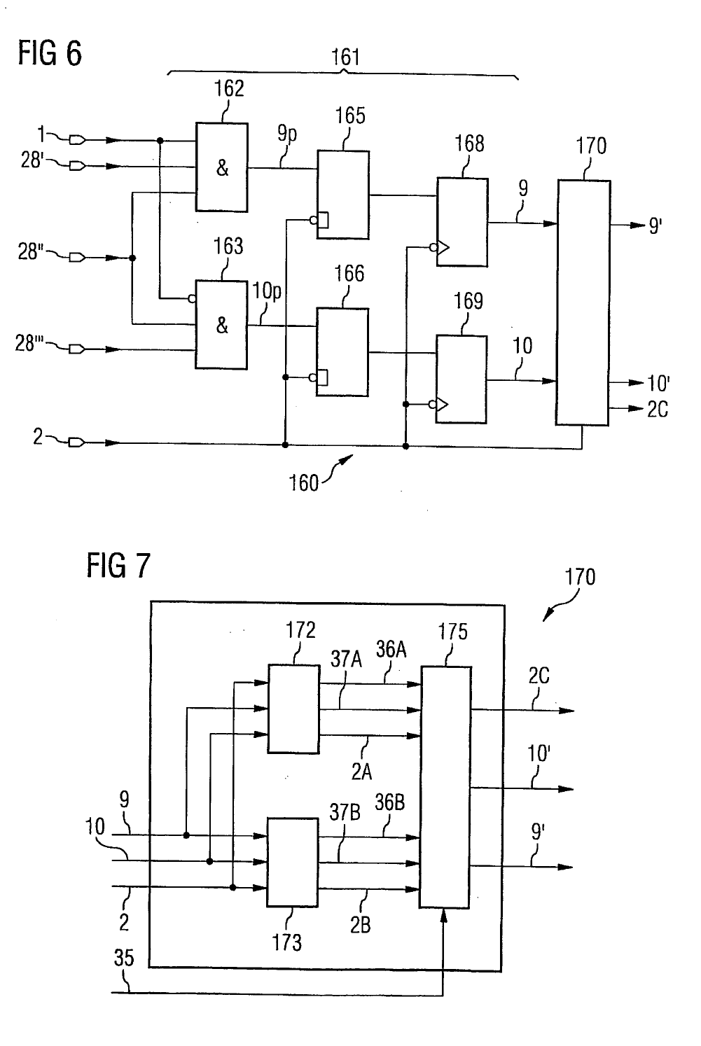

FIG. 6 shows the structure of a digital phase detector according to an exemplary embodiment of the invention,

FIG. 7 shows the structure of a converter circuit for converting the bit width of digitally coded output signals of the phase detector,

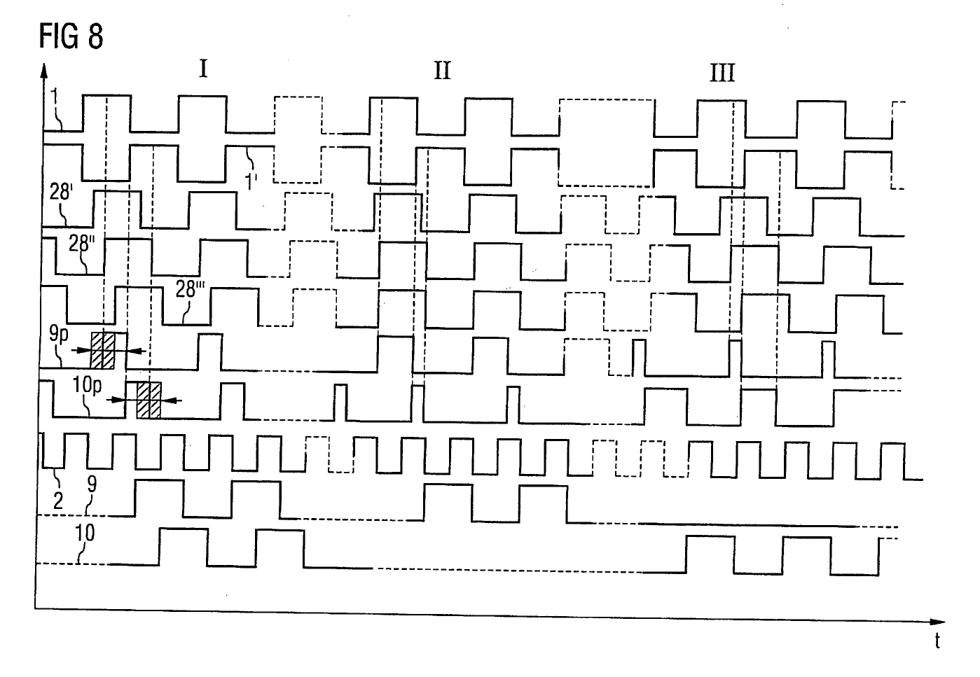

FIG. 8 illustrates the time progression of signals in the phase comparison by the digital phase detector,

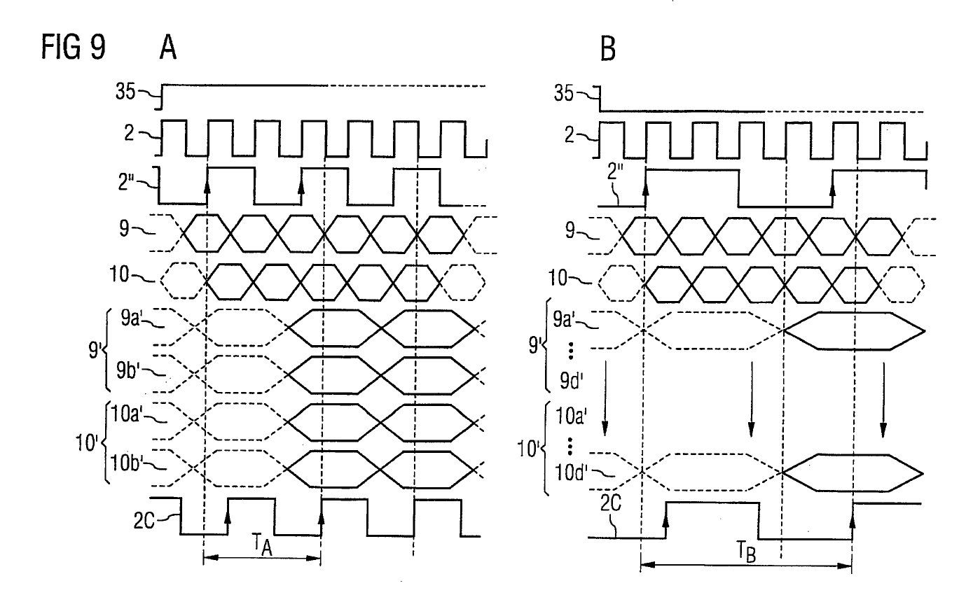

FIG. 9 illustrates the time progression of signals in the conversion of the bit width of the digitally coded output signals of the digital phase detector,

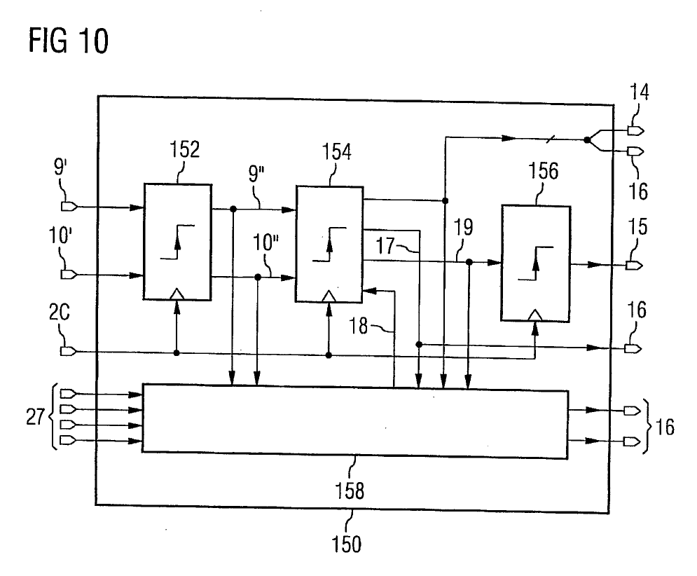

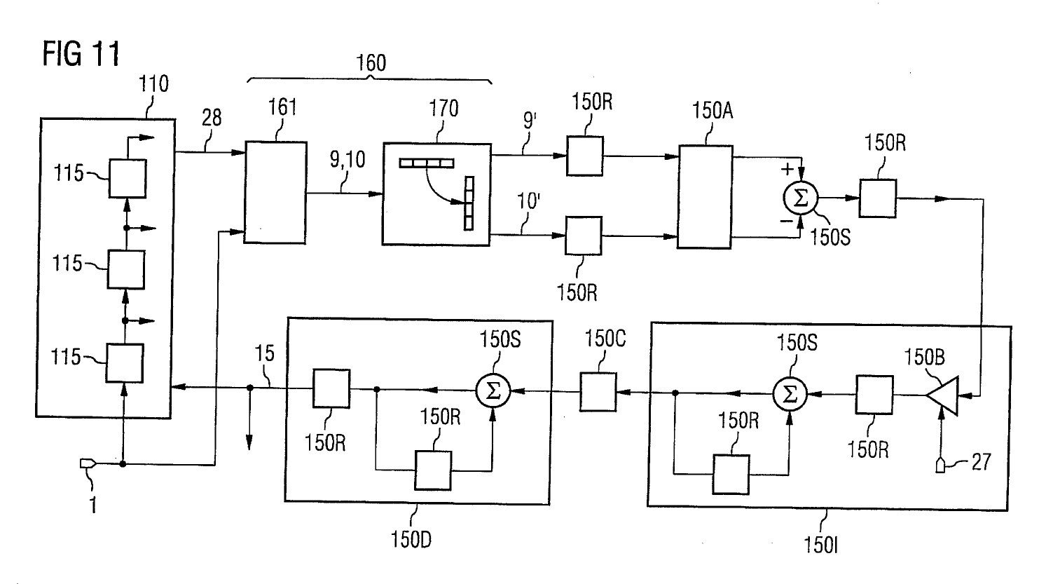

FIG. 10 shows the structure of digital control means for the master delay loop,

FIG. 11 shows an alternative form of the master delay loop,

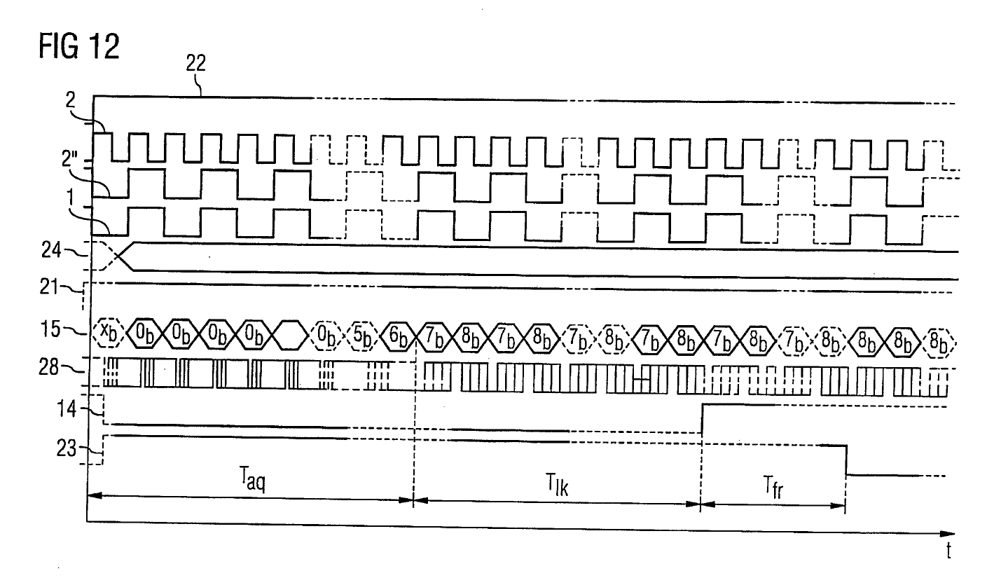

FIG. 12 shows the time progression of signals of the master delay control loop in the delay regulation,

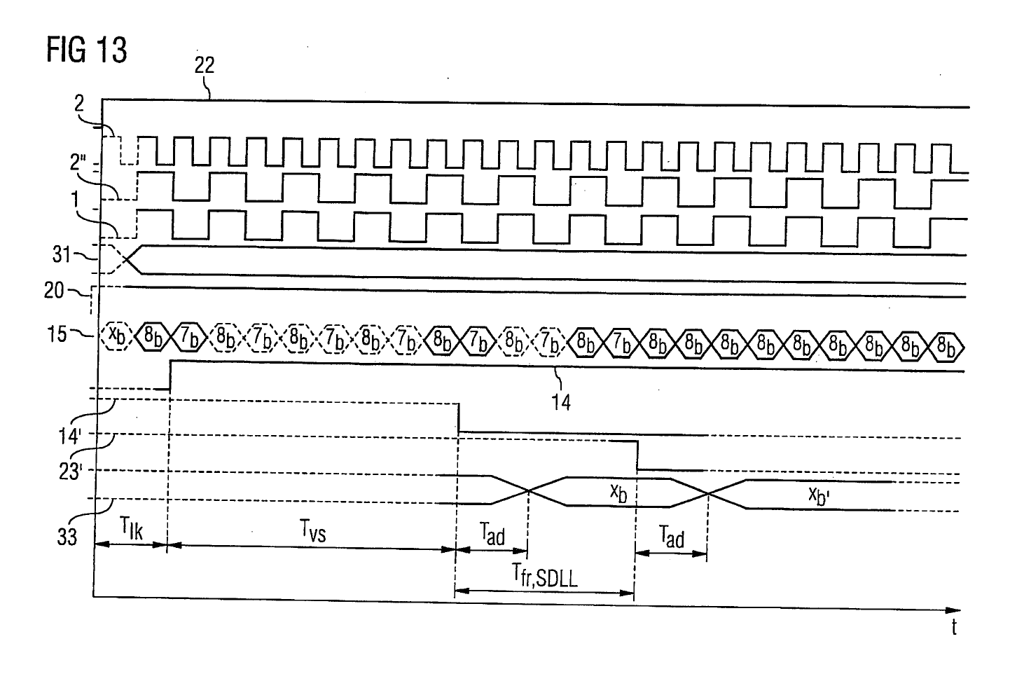

FIG. 13 shows the corresponding time progression of signals of the slave delay control loop,

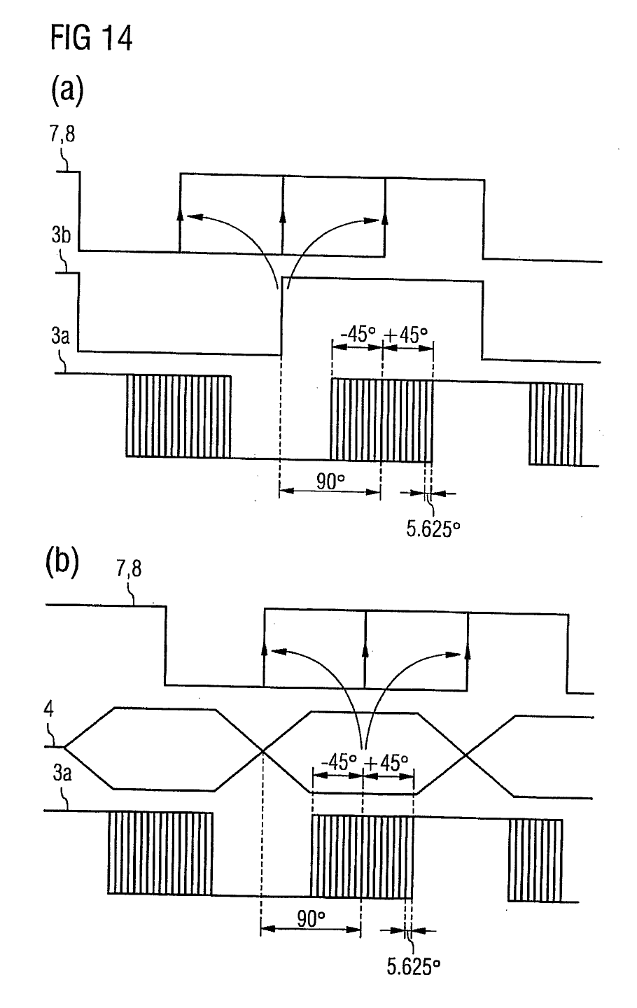

FIG. 14 illustrates the time progression of control, clock, data and sampling signals for a memory device, FIG. 14(a) illustrating the case of a writing mode of operation and FIG. 14(b) illustrating the case of a reading mode of operation,

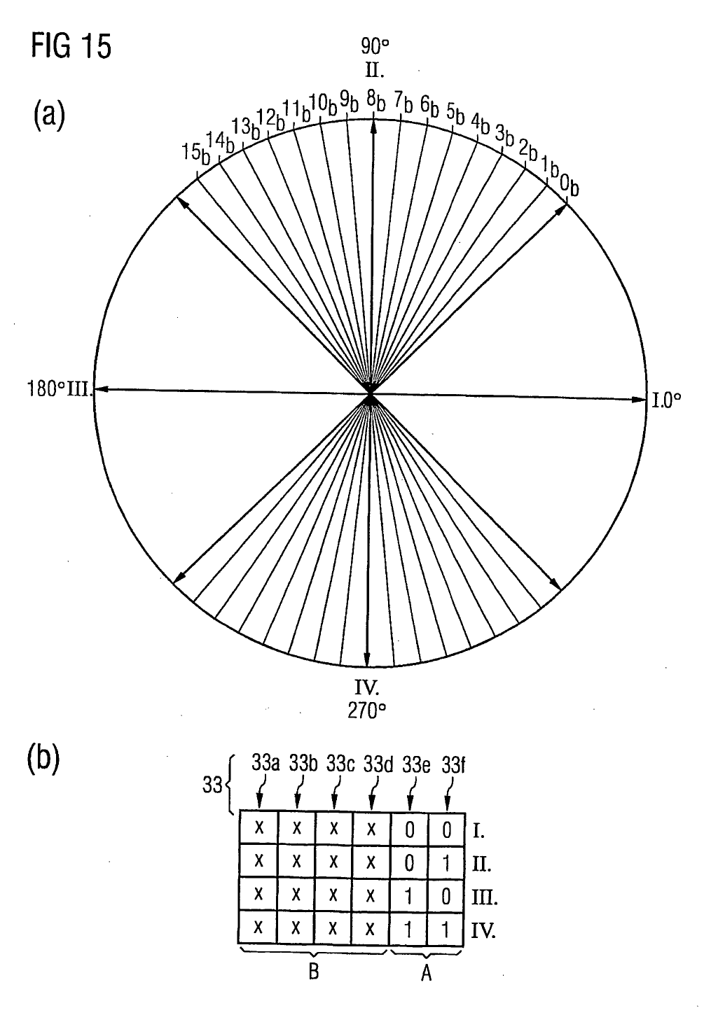

FIG. 15(a) illustrates in a circular diagram the selection of the phase relations of delayed clock signals that are generated according to the present invention, and FIG. 15(b) illustrates the use of a phase selection control signal for selecting a desired phase relation of the delayed clock signal, and

FIG. 16 illustrates the basic mode of operation of a delay locked loop, wherein in the case of FIG. 16(a) a reference clock signal is formed directly by the clock signal to be delayed, while in the case of FIG. 16(b) the reference clock signal is derived externally from the clock signal to be delayed.

In the following description the same reference numerals have been used throughout for similar components.

FIG. 1 shows diagrammatically a circuit block for the generation and synchronization of data signals and sampling signals in a memory interface for a memory device. The memory device may in particular be a so-called double data rate memory (DDR memory).

The device comprises a master delay control loop 100, to which is fed a first clock signal 1 to be delayed. The master delay control loop 100 delays the clock signal 1 by a specific time, a defined phase relationship being adjusted between the first clock signal 1 and the delayed clock signal. To this end the delay in the master delay control loop 100 is preferably a specific fraction of the cycle duration of the clock signal 1.

Furthermore, a second clock signal 2, which is generated independently of the first clock signal 1, is fed to the master delay control loop 100. The second clock signal 2 is thus asynchronous with respect to the first clock signal 1. The frequency of the second clock signal 2 corresponds to twice the frequency of the first clock signal 1. The second clock signal 2 may be made available for example by means of a phase locked loop.

In order to establish a fixed phase relationship between the delayed clock signal and the clock signal 1, the master delay control loop 100 generates internally a digital control signal, via which the signal delay means of the master delay control loop 100 are controlled. The digital control signal of the master delay control loop 100 is available at signal outputs of the master delay control loop 100 and is used in order to control slave delay control loops 200, 300.

The delay means of the master delay control loop 100 as well as of the slave delay control loops 200, 300 are formed by identical delay chains with a plurality of delay stages. The digital control signal that is generated by the master delay control loop 100 controls in particular the delay that is made available by one of the delay stages of the delay means. By tapping at the outputs of the individual delay stages of the delay means of the slave delay control loops 200, 300, clock signals can be tapped, which after adjustment of the master delay control loop have in each case a delay that corresponds to a defined fraction of the cycle duration of the first clock signal 1. The output signals of the individual delay stages of the slave delay control loops 200, 300 are in each case fed to multiplexer means 220, 320, which by selection and interpolation of the various delayed clock signals generate output clock signals 3a, 3b, 3c.

The phase relationship of the output clock signals 3a, 3b, 3c to the first clock signal 1 is adjusted by suitably driving the multiplexer means 220, 320. For this purpose corresponding values are selected from lists stored in memory means 250, 350 and transferred to control registers 230, 330, which feed a corresponding phase selection control signal to the multiplexer means 220, 320.

The output clock signal 3a serves as input signal for a sampling signal generation block 50, which generates a sampling signal 3′ on the basis of the output clock signal 3a. The sampling signal generation block 50 is in this connection basically configured so as to provide the output clock signal 3a with an envelope so that the sampling signal 3′ consists of sequences of pulses that have the same frequency and phase relation as the output clock signal 3a. The output clock signal 3b is fed to a synchronisation block 60 that synchronises, with the output clock signal 3b, write data signals 6 to be written in the memory, in order to generate in this way for writing procedures a memory data signal 4 that is synchronised with the output clock signal 3b.

Whereas the first clock signal 1 is fed as signal to be delayed to the slave delay control loop 200, in the case of the slave delay control loop 300 the sampling signal 3′ serves as clock signal to be delayed. In this connection there is a particular advantage in using delay control loops that, in contrast to phase locked loops, do not depend on a completely periodic clock signal being fed to them but are also suitable for clock-type signals. By means of the slave delay control loop 300 a desired phase relationship between the sampling signal 3′ and the output clock signal 3c is thus adjusted for reading procedures. The output clock signal 3c is fed to a synchronisation block 70, which on the basis of a memory data signal 4 received from the memory generates a read data signal 5 synchronised with the first clock signal 1. For this purpose the first clock signal 1 is also fed as further clock signal to the synchronisation block 70.

The synchronisation blocks 60 and 70 thus effect a synchronisation of the write and read data signals 5, 6 with the internal clock pulse domain of the memory interface. For this purpose the synchronisation blocks 60, 70 include flip-flop elements that are controlled by the corresponding clock signals 1, 3b, 3c. In addition the synchronisation blocks 60, 70 effect a matching of the bit width of the signal lines, in which the write and read data signals 6 may for example have a bit width of eight bits, and the memory data signal 4 has a bit width of four bits. Such a configuration is typical of DDR memories that implement the internal communication between the memory and the memory interface with a doubled data rate as compared to the external communication between the memory interface and other components.

The arrangement illustrated in FIG. 1 thus uses only one master delay control loop 100 in order to make available output clock signals 3a, 3b, 3c with different phase relationships for a bidirectional communication with the memory. Preferably further slave delay control loops are provided in order to be able to assemble a cluster of for example four, eight or more memory interfaces with the same master delay control loop 100. For each interface a slave delay loop corresponding to the slave delay control loop 200 would then be provided in order to make available a sampling signal 3′ and an output clock signal 3b for the synchronisation of writing procedures. Furthermore, for each of the interfaces a slave delay control loop corresponding to the slave delay control loop 300 would be provided in order to make available an output clock signal 3c for the synchronisation of reading procedures.

For the bidirectional use the arrangement of FIG. 1 is provided with switching means 40, by means of which signal connections whose use is not necessary for the intended application can be interrupted. Thus, for example, the feed of the sampling signal 3′ to the slave delay control loop 300 and the connection of the data memory signal 4 to the synchronisation block 70 are interrupted in transmission procedures. In this way an unnecessary loading of the sampling signal output and of the memory data signal output can be avoided, and a bidirectional data transfer with the memory data signal 4 is possible.

FIG. 2 shows the structure of a further circuit block of the memory interface, which is used for the generation and synchronisation of clock, command and address signals. A slave delay control loop 400, multiplexer means 420, a memory 450 and a control register 430 of this circuit block correspond to the slave delay control loop 200, the multiplexer 220, the memory 250 and the control register 230 of FIG. 1. The delay control loop 400 is again controlled by the digital control signal generated by the master delay control loop 100. The first clock signal 1 serves as input signal to be delayed. Address and command signals 11, 12, 13 are passed to the memory as address and command signals 11′, 12′, 13′ synchronised with the first clock signal 1, via flip-flop elements 460 that are driven by the first clock signal 1. Output clock signals 7, 8 of the slave delay control loop 400 are transmitted as control clock signals to the memory. In this connection the output clock signal 7 differs from the output clock signal 8 simply as regards its sign, i.e. it is shifted by 180° in phase. The object of the slave delay control loop 400 in this case is to ensure that the clock signals 7, 8 are synchronised with the address and command signals 11′, 12′, 13′ at the memory site. In addition a defined phase relationship to the sampling signal 3′ and the data signal 4 is necessary. The command and address circuit block of FIG. 2 is configured for the joint use by a plurality of memories. In this connection buffers or line drivers 45 are provided in order to ensure the necessary signal strengths at the site of the respective memory.

FIG. 3 shows the structure of the master delay control loop 100 according to a first embodiment. The first clock signal 1 is fed via a buffer 45, a multiplexer 130 and a further buffer 45 to a delay means in the form of a delay chain 110, in which the buffers 45 serve for an appropriate matching of the signal strengths. The delay chain 110 comprises a plurality of identical delay elements 115 connected in series. The respective delay elements 115 are configured as digitally controllable delay elements that are sufficiently well known to the person skilled in the art. The delay elements 115 effect in each case a delay of their input signal by a specific time, which can be identically adjusted by a digital control signal 15 for each of the delay elements 115.

A delayed clock signal can thus be tapped in each case at the outputs of the delay elements 115, the delay of the clock signal corresponding to a multiple of the delay made available by an individual delay element 115. At the outputs of the individual delay elements 115, tapped delayed clock signals as well as the input signal of the delay chain 110 are fed to a multiplexer 120. The multiplexer can be controlled by a phase selection control signal 25. Depending on the phase selection control signal 25, the delayed clock signals at the signal input of the multiplexer 120 are passed on to its signal output. The output signal 28 of the multiplexer 120 comprises a plurality of subsignals, which in each case are tapped at one of the outputs of the delay elements 115. In the present case three delayed clock signals are involved, which are tapped at outputs of the delay elements 115 that correspond to three identical delay stages. The delay stages may in this connection comprise one or more of the delay elements 115. It is possible for example to tap the subsignals at the outputs of a first, second and third delay element 115. For a larger delay, the subsignals can be tapped at the outputs of a second, fourth and sixth delay element 115. The number of delay elements 115 in a delay stage can be selected with the multiplexer 120, corresponding to the phase relationship to be adjusted. The number of the delay elements 115 in a delay stage thus represents a form of coarse adjustment of the delay. A fine adjustment is carried out by means of the digital control signal 15 directly at the individual delay elements 115.

The output signal of the multiplexer 120 is fed via a buffer 45 to a comparison means in the form of a phase detector 160. The phase detector 160 is digitally configured and is controlled by the second clock signal 2. The first clock signal 1 is in addition fed from the multiplexer 130 via a buffer 45 to the phase detector 160. The phase detector 160 is thus configured so as to compare a delayed clock signal 28, comprising three subsignals, of the delay chain 110 with the non-delayed first clock signal 1 as regards the relative phase relation. On the basis of the phase comparison, digitally coded comparison signals 9′, 10′ are generated, which reflect the deviation of the delayed clock signal 28 from the desired phase relation. In addition the phase detector 160 makes available a clock signal 2C associated with the comparison signals 9′, 10′.

The comparison signals 9′, 10′ and the associated clock signal 2C are fed to a control means 150 of the master delay control loop 100. The control means 150 of the master delay control loop 100 generates on the basis of the comparison signals 9′, 10′ the digitally coded control signal 15 for the delay elements 115. In particular the control means 150 includes a loop filter for the control loop of the master delay control loop 100, in order thereby to ensure the stability of the delay regulation.

In addition to the digital control signal 15 for the delay elements 115, the control means 150 make available status signals 14, 16, which may be used for example for monitoring and checking purposes. The control means 150 can be adjusted via control signals 27.

For test purposes it is furthermore possible to feed the second clock signal 2 via the multiplexer 130 into the delay chain 110. This is effected by appropriately driving the multiplexer 130 with an input clock selection signal 24. Before the second clock signal 2 is fed into the multiplexer 130, the frequency of the second clock signal is however halved by a frequency halving device 140, so that a frequency-altered second clock signal 2″ of half the frequency is produced.

In addition control signals 21, 22, 23 are fed to the master delay control loop 100, which effect an activation, resetting or “freezing” of the master delay control loop 100. The term “freezing” is understood to mean that the regulation is suspended and the further operation of the delay chain 110 is effected with a fixed digital control signal 15.

In addition a phase locked loop 500 is illustrated diagrammatically in FIG. 3, which serves for the independent generation of the second clock signal 2.

An alternative structure of a master delay control loop 100′ is illustrated in FIG. 4. The structure corresponds in large parts to that of FIG. 3, and elements corresponding to one another have been provided with the same reference numerals. A renewed explanation of such elements is omitted hereinafter.

A basic difference compared to the master delay control loop 100 of FIG. 3 is that the master delay control loop 100′ of FIG. 4 is configured to receive an advance (preliminary) clock signal 2′, which has the same frequency as the first clock signal 1. In order to be able to control the phase detector 160 again with the second clock signal 2, which has twice the frequency of the first clock signal 1, a doubling of the frequency of the advance clock signal 2′ takes place internally in the master delay control loop 100′ of FIG. 4 in order to obtain the second clock signal 2. If in the master delay control loop 100′ of FIG. 4 the second advance clock signal 2′ is fed via the multiplexer 130 into the delay chain 110, then no internal frequency halving takes place since the advance clock signal 2′ already has the same frequency as the first clock signal 1. The advance clock signal 2′ is made available by a phase locked loop 500.

FIG. 5 shows the structure of the slave delay control loop 200. The first clock signal 1 is fed via a buffer 45 to a first multiplexer 260 of the slave delay control loop 200. The output signal of the first multiplexer 260 is passed on either directly or via a flip-flop element 265 to a second multiplexer 270 to the slave delay control loop 200. The output signal of the second multiplexer 270 is fed to delay means of the slave delay control loop 200 in the form of a delay chain 210. The delay chain 210 is configured identically to the delay chain 110 of the master delay control loop 100, 100′. The input signal of the delay chain 210 as well as the respective output signals of delay elements 215 of the delay chain 210 are fed to the multiplexer means 220. Depending on a phase selection control signal 33, two of the output signals of the delay chain 210 are passed on to an interpolator 225, which by interpolation of its two input signals generates the output clock signals 3a, 3b. The interpolator 225 is in this connection likewise driven by the phase selection control signal 33 and ensures thereby a fine adjustment of the phase relationship between the output clock signals 3a, 3b and the clock signal 1.

In contrast to the master delay control loop 100, 100′, in the slave delay control loop 200 no intrinsic internal control loop is provided. Instead, the control of the delay elements 215 of the delay chain 210 is performed by the same digital control signal 15 that is used internally by the master delay control loop 100, 100′. For this purpose the digital control signal 15 of the master delay control loop 100, 100′ is extracted as output signal and fed as input signal to the slave delay control loop 200. The digital control signal 15 is stored in a control register 280 of the slave delay control loop 200 if a status signal 14′ derived from the status signal 14 of the master delay control loop 100, 100′ indicates that the master delay control loop 100, 100′ is stably adjusted or locked. The control register 280 is driven via a buffer 45 with the clock signal that can be tapped at the output of the first multiplexer 260. In the normal operating mode of the slave delay loop 200 this clock signal is the first clock signal 1.

Furthermore, with the slave delay control loop 200 it is also possible to feed the second clock signal 2, which is passed via a buffer 45 to a frequency halving device 240, through the first multiplexer 260 and second multiplexer 270 into the delay chain. In addition it is possible to feed, instead of the first clock signal, the sampling signal 3′ by means of the multiplexer 270 into the delay chain 210. In this way the mode of operation is obtained which has been explained with respect to FIG. 1 in the case of the slave delay control loop 300. The slave delay control loops 300 and 400 of FIG. 1 thus correspond in their structure to that of the slave delay control loop 200, as has been explained with respect to FIG. 5. The clock signal to be delayed of the slave delay control loop 200, i.e. the first clock signal 1, the frequency-altered second clock signal 2″ or the sampling signal 3′, can be selected by means of an input clock selection signal 31 via the multiplexers 260 and 270.

FIG. 6 shows the structure of the digital phase detector of the master delay control loop 100, 100′. Input signals of the phase detector 160 are formed by the first clock signal 1 and the delayed clock signal 28, which comprises three subsignals 28′, 28″, 28″′. Flip-flop elements 165, 166, 168, 169 of the phase detector 160 are controlled by the second clock signal 2, the frequency of which is twice the frequency of the first clock signal 1.

The subsignals 28′, 28″, 28″′ of the delayed clock signal 28 in each case have a delay compared to the clock signal 1 that forms a multiple of a delay unit that is determined by the delay of the previously described delay stages. Specifically, the subsignal 28′ has a delay that corresponds to a unit delay of a delay stage. The subsignal 28″ has a delay that corresponds to twice the unit delay. The subsignal 28″′ has a delay that corresponds to three times the unit delay.

The phase detector 160 includes on the input side a first AND interconnection means 162, whose input signals are formed by the first clock signal 1, the subsignal 28′ and the subsignal 28″, and a second AND interconnection means 163, whose input signals are formed by the inverted first clock signal 1′, the subsignal 28″ and the subsignal 28″′. The output signals of the AND interconnection means 9p, 10p are fed to latch-flip-flop elements 165 and 166. The clock input of the latch-flip-flop elements 165, 166 is fed with the second clock signals 2. The output signals of the latch-flip-flop elements 165, 166 are in each case fed to a D-flip-flop element 168 and 169. The clock pulse inputs of the D-flip-flop elements 168, 169 are in turn fed with the second clock signal 2. The AND interconnection means 162, 163 and the flip-flop elements 165, 166, 168, 169 together form an interconnection and sampling block 161, which executes the essential functions of the phase detector 160.

The flip-flop elements 165, 168 arranged downstream of the first AND interconnection means 162 have in each case an inverting clock signal input, while the flip-flop elements 166, 169 arranged downstream of the second AND interconnection means 163 have a non-inverting clock signal input.

The output signals 9, 10 of the D-flip-flop elements 168, 169 are fed to a converter circuit 170, which converts the digitally coded signals 9, 10 having in each case a bit width of one, into digitally coded signals 9′, 10′ with a larger bit width. For the digitally coded signals 9′, 10′ a correspondingly lower frequency of the associated clock signal 2C is thus also obtained at the same time. The associated clock signal 2C, which is derived in a suitable manner from the second clock signal 2, is likewise made available as output signal by the converter circuit 170.

FIG. 7 shows more precisely the structure of the converter circuit 170. The output signals 9, 10 of the D-flip-flop elements 168, 169 are fed within the converter circuit 170 to first converter means 172 as well as to second converter means 173.

The first converter means 172 effect for each of the signals 9, 10 a conversion from a bit width of one to a bit width of two, i.e. they accomplish overall a conversion of the bit width from two to four. Output signals of the converter means 172 are formed by a 2-bit signal 36A corresponding to the signal 9 and a 2-bit signal 37A corresponding to the signal 10, as well as by an associated clock signal 2A derived from the second clock signal 2.

The second converter means 173 accomplish for each of the signals 9, 10 a conversion from a bit width of one to a bit width of four, so that overall a conversion of the bit width from two to eight takes place. Output signals of the converter means 173 are formed by a 4-bit signal 36B corresponding to the signal 9 and by a 4-bit signal 37B corresponding to the signal 10, as well as by an associated clock signal 2B derived from the second clock signal 2.

The output signals of the converter means 172, 173 are fed to a multiplexer, which is driven by means of a bit width selection signal 35. By means of a bit width selection signal 35 either the output signals of the first converter means 172 or those of the second converter means 173 can be selected as output signals 2C, 9′, 10′ of the converter circuit 170.

FIG. 8 shows the time progression of signals of the master delay control loop 100, 100′, in particular in connection with the phase comparison through the phase detector 160. The first clock signal 1 and the inverted first clock signal 1′, the subsignals 28′, 28″ and 28″′ of the delayed clock signal 28, the output signals 9p, 10p of the AND interconnection means 162, 163, the second clock signal 2, as well as the output signals 9, 10 of the D-flip-flop elements 168, 169 are illustrated. The diagram includes three time regions I, II and III. Vertical dotted lines indicate the signals that are superimposed by the AND interconnection means 162, 163.

In the region I the delayed signal 28 has the desired phase relationship to the first clock signal 1. The subsignals 28′, 28″, 28″′ of the delayed clock signal 28 are delayed relative to this by ⅛, ¼ and ⅜, respectively, of the cycle duration of the first clock signal 1. For the output signal 9p of the first AND interconnection means 162 a signal is produced that has pulses whose width corresponds to ¼ of the cycle duration of the first clock signal 1 and thus to half the pulse width of the first clock signal 1. The same applies to the output signal 10p of the second AND interconnection means 163, in which the position of the pulse in the output signal 10p of the second AND interconnection means 163 is displaced relative to the position of the pulses in the output signal 9p. The descending edge of the pulses in the output signal 9p thus coincides in time with the position of the ascending edge of the pulses in the output signal 10p.

In the region II the delayed signal 28 has a smaller delay compared to the region I, whereby an enlarged pulse width is obtained for the output signal 9p of the first AND interconnection means 162 and a reduced pulse width is obtained for the output signal 10p of the second AND interconnection means 163, as is illustrated in FIG. 8.

In the region III the delayed signal 28 has a larger delay compared to the region I, whereby a reduced pulse width is obtained for the output signal 9p of the first AND interconnection means 162 and an enlarged pulse width is obtained for the output signal 10p of the second AND interconnection means 163, as is illustrated in FIG. 8.

The output signals 9p, 10p of the AND interconnection means 162, 163 are thus pulse-width modulated signals, whose pulse width represents the relative deviation of the delay of the delayed signal 28 with respect to the first clock signal 1 from a specified delay value, which in this case is determined so that the subsignals 28′, 28″, 28″′ are in each case delayed by a further ⅛ of the cycle duration of the first clock signal 1. In this connection the pulse width modulation of the output signal 9p of the first AND interconnection means 162 is such that the pulse width decreases with increasing delay. However, the pulse width of the output signal 10p of the second AND interconnection means 163 increases with increasing delay. In the balanced case, i.e. when both pulse widths are identical to ¼ of the cycle duration of the first clock signal 1, the subsignal 28′ has a phase relation of 45°, the subsignal 28″ has a phase relation of 90° and the subsignal 28″′ has a phase relation of 135° with respect to the first clock signal 1. In addition it can be recognised from FIG. 8 that the sum of the pulse widths of the output signals 9p, 10p of the AND interconnection means 162, 163 is always equal to half the cycle duration of the first clock signal 1, and corresponds to the pulse width of the first clock signal 1.

The sampling of the pulse-width modulated signals 9p, 10p by the flip-flop elements 165, 166, 168, 169 is illustrated in the lower region of FIG. 8. For this purpose the flip-flop elements 165, 166, 168, 169 are driven, i.e. clocked, by the second clock signal. As can be recognised from FIG. 8, the second clock signal 2 has no special phase relationship with respect to the first clock signal 1. The frequency of the second clock signal 2 is twice the frequency of the first clock signal 1. In this way it is possible to sample in a controlled manner the pulse-width modulated signals 9p, 10p by the second clock signal 2. This takes place first of all through the latch-flip-flop elements 165, 166, which are driven depending on the value of the second clock signal 2. This means that the latch-flip-flop elements 165, 166 take over and retain the value of their input signal 9p, 10p as soon as the second clock signal 2 adopts at its clock input a specific (high or low) signal level. The latch-flip-flop element 165, which has an inverting clock signal input, responds in this connection at the low signal level of the second clock signal 2, whereas the latch-flip-flop element 166, which has a non-inverting clock signal input, responds at the high signal level of the second clock signal 2. The flip-flop elements 168, 169, which receive the output signals of the latch-flip-flop elements 165, 166 as input signals, are D-flip-flop elements, which depending on signal edges of the second clock signal 2 at their respective clock input pass on to and hold their input signal at their signal output. In this connection the change of state at the signal output of the D-flip-flop element 168, which has an inverting clock signal input, takes place with a descending edge of the second clock signal 2, whereas the change of state at the signal output of the D-flip-flop element 169, which has a non-inverting clock signal input, takes place with an ascending edge of the second clock signal.

The result of the sampling by the flip-flop elements 165, 166, 168, 169 are digital output signals 9, 10, in which the output signal 9 of the D-flip-flop element 168 contains a sequence of pulses if the delay of the delayed clock signal 28 is less than or equal to the delay in the balanced state, i.e. if the phase relations of the subsignals 28′, 28″, 28″′ are equal to or less than 45°, 90° and 135°. In principle the sampling is thus based on checking whether the pulse width of the pulse-width modulated signal 9p exceeds the pulse width of half the cycle duration of the second clock signal 2. If this is the case, a sequence of pulses is produced in the output signal 9 of the D-flip-flop element 168 that has a defined pulse duty ratio and whose frequency corresponds to half the frequency of the second clock signal 2. If the pulse width of the pulse-width modulated signal 9p lies below the pulse width or half the cycle duration of the second clock signal 2, the output signal 9 of the D-flip-flop element 168 does not exhibit any pulses.

A similar situation exists as regards the output signal 10 of the D-flip-flop element 169, though in this case the sampling checks whether the pulse-width modulated signal 10p has a pulse width that exceeds the pulse width or half the cycle duration of the second clock signal 2. If this is the case, a sequence of pulses is again produced in the output signal 10 of the D-flip-flop element 169 that has a fixed pulse duty ratio and whose frequency is half the frequency of the second clock signal 2.

Overall, pulses in the output signal 9 of the D-flip-flop element 169 thus indicate that the adjusted delay is too small, while pulses in the output signal 10 of the D-flip-flop element 169 indicate that the adjusted delay is too large. In the case where the adjusted delay coincides with the desired delay, pulses are produced both in the output signal 9 of the D-flip-flop element 168 as well as in the output signal 10 of the D-flip-flop element 169. The output signals 9, 10 of the D-flip-flop elements 168, 169 thus represent digitally coded signals with in each case a bit width of one, which reflect the deviation of the adjusted delay from the desired delay. The digitally coded signals 9, 10 have a fixed pulse duty ratio, determined by the second clock signal 2, of one to one and have a fixed phase relationship with respect to the second clock signal 2, in which ascending edges of pulses in the digitally coded signal 9 coincide in time with descending edges in the second clock signal 2. However, ascending edges of pulses in the digitally coded signal 10 coincide in time with ascending edges of the second clock signal 2. The clock signal belonging to the digitally coded signals 9, 10 can thus be derived from the second clock signal 2.

FIG. 9 illustrates the conversion of the bit widths of the digitally coded signals 9, 10 in the converter circuit 170. In this connection the illustration under A corresponds to the conversion of the bit width from two to four by the converter means 172, while the illustration under B corresponds to the conversion of the bit width from two to eight by the converter means 173. Which of the two cases is realised by the converter circuit 170 is determined by the state of the bit width selection signal 35.

The case A describes a conversion of the bit width from two to four. Apart from the bit width selection signal 35, also shown are the second clock signal 2, a clock signal 2″ of half the frequency derived from the second clock signal 2, the digitally coded output signals 9, 10 of the sampling, output signals of the bit width conversion 9′, 10′, and a clock signal 2C belonging to the output signals 9′, 10′ of the bit width conversion. The digitally coded input signals 9, 10 of the converter circuit 170 are in this case shown with a finite edge steepness and including the complementary signal, so that an “eye” is formed for each pulse and each pause of the digitally coded signals 9, 10 illustrated in FIG. 8. Such an eye represents in this connection the elementary information unit of the digitally coded signals 9, 10, so that from these digitally coded signals 9, 10 the information can be read out with the frequency of the second clock signal 2. On the basis of the information read out with the frequency of the second clock signal 2 there are generated, over in each case two clock pulse cycles of the second clock signal 2, for the digitally coded signal 9 and the digitally coded signal 10 in each case two digitally coded signals 9a′, 9b′ and 10a′, 10b′, which contain the complete information, but on account of the doubled bit width are of half the frequency. The signals 9a′ and 9b′ form subsignals of the digitally coded output signal 9′ of the converter circuit 170, and the signals 10a′ and 10b′ form subsignals of the output signal 10′ of the converter circuit 170. At the same time, in the conversion the phase mismatch of half a cycle duration of the second clock signal 2 between the digitally coded signal 9 and the digitally coded signal 10 is balanced. This means that between the input of the digitally coded signals 9, 10 in the converter means 172 and the generation of the converted signals 9′, 10′ that correspond as regards their bit width, a time shift T_{A} that corresponds to 2.5 times the cycle duration of the second clock signal 2 is obtained at the output of the converter circuit 170. The converter means 172 furthermore make available a clock signal 2C belonging to the digitally coded output signals 9′, 10′ of the converter circuit 170, which clock signal has half the frequency of the second clock signal 2 and whose ascending pulse edges coincide in time with regions of “eyes” of the subsignals 9a′, 9b′, 10a″, 10b′ of the converted signals 9′, 10′.

In the configuration of the converter circuit 170 illustrated under B, i.e. when the bit width selection signal 35 assumes a low value, a bit width conversion takes place that resembles the conversion already described under A, though with a conversion of the bit width from two to eight. This means that, in contrast to the case described under A, the output signals 9′, 10′ of the converter circuit 170 in each case comprise four subsignals 9a′ to 9d′ and 10a′ to 10d′, which in each case have a quarter of the frequency of the digitally coded signals 9, 10. The associated clock signal 2C made available in this case thus has a cycle duration that is four times that of the second clock signal 2. The frequency-altered second clock signal 2″ having a quarter of the frequency of the second clock signal 2 is therefore also illustrated under B. Between the input of the digitally coded signals 9, 10 in the converter means 173 and the generation of the digitally coded output signals 9′, 10′ of the converter circuit 170, a time duration TB of 4.5 times the cycle duration of the second clock signal 2 is produced in this case.

An advantage of this bit width conversion, which can be recognised from FIG. 9, is the fact that the digitally coded signals 9′, 10′ on account of their smaller frequency also have a reduced sensitivity to fluctuations in their phase relation with respect to the associated clock signal 2C and can be transmitted over a longer distance. The phase detector 160 thus makes available at its signal output a comparison signal in the form of the digitally coded signals 9′, 10′ that has a lower sensitivity to interferences.

FIG. 10 shows the structure of the digital control means 150 of the master delay control loop 100, 100′. The digitally coded output signals 9′, 10′ of the phase detector 160 are fed to the digital control means 150. The control means 150 comprises register means 152, 154, 156, which are controlled by the clock signal 2C belonging to the digital output signals 9′, 10′ of the phase detector 160. In this connection the register means 152 basically has the function of an input register that undertakes a conversion of the input signals 9′, 10′ as regards their coding. In this case a conversion from a thermometer coding to a binary value coding may specifically be involved. Corresponding output signals 9″, 10″ of the register means 152 are fed to the register means 154, which basically performs the function of a loop filter for the control loop. An output signal 19 of the register means 154 is fed to the register means 156, which essentially performs the function of an output register. An output signal of the register means 156 then forms the digital control signal 15 for controlling the delay elements 115, 215 of the master delay control loop 100, 100′ and of the slave delay control loops 200, 300, 400. The digital control signal 15 has in this connection a bit width of 12.

The digital control means 150 furthermore include a write-read register means 158, to which are fed the output signals of the register means 152 and 154. Internal control signals 17, 18 allow a transfer of information between the register means 154 and the write-read register means 158. The write-read register means 158 is used in particular for programming the digital control means 150, for which purpose the control signals 27 are fed to the write-read register 158. For test and monitoring purposes the write-read register means 154 generates status signals 14, 16. The status signals 14, 16 are made available as output signals to the control means 150.

FIG. 11 shows an alternative representation of the master delay control loop 100, 100′, from which in particular the implementation of the control loop is evident. A delayed output signal 28 of the delay chain 110 with the delay elements 115 is fed together with the non-delayed first clock signal 1 to the phase detector 160. The output signals 9, 10 to the interconnection and sampling block 161 are converted in the converter circuit 170 into the digitally coded signals 9′, 10′ with enlarged bit width. After passing through registers 150R and the coding conversion in block 150A, a difference calculation is performed in the summation point 150S. In this connection specifically the signal based on the comparison signal 10′ and that indicates too large a delay, is subtracted from the signal based on the comparison signal 9′ and that indicates too small a delay. In this way a single signal is obtained that represents a measure of how much the delay has to be adapted. After passing through a further register 150R the summated signal is fed to an integrator block 150I, which provides an integral factor to the control loop. The integral factor can in this connection be adjusted via a control signal 27 that is fed to an amplification element 150B. A further register 150R is arranged at the output of the amplification element 150B, following which a summation is carried out with an output signal of the integration block 150I back-coupled via a register 150R.

The output signal of the integrator block 150I is fed to a non-linear block 150C, which in the present case is configured so as to calculate the sign of its input signal. The non-linear block 150C thereby ensures the stability of the locked loop. The output signal of the non-linear block, which on account of its simple configuration in the form of a sign calculation has an output signal with a smaller bit width, is for the purposes of generating the digital control signal 15 for the delay elements 115 fed to an output shift register whose value is increased or reduced depending on the output signal of the non-linear block 150C. The output register 150D includes in this connection a summation point 150S and a signal feedback of the output signal of the summation point 150S to the summation point 150S. A further register 150R is arranged at the output of the output register 150D.

The bit width of the digital control signal 15 that is generated by the regulating loop is determined by the configuration of the output register 150D. The digital control signal 15 is on the one hand fed to the delay chain 110 of the master delay control loop 100, 100′, and on the other hand to the delay chains of the slave delay control loops 200, 300, 400 (not shown in FIG. 11). The functions of the components 150R, 150A, 150B and 150C shown in FIG. 11 are carried out by the register means 152, 154, 156, which are shown in FIG. 10, in conjunction with the write-read register means 158, likewise shown in FIG. 10.

In particular, the advantage of the digitally coded output signals 9′, 10′ of the phase detector 160 can be seen in the illustration of FIG. 11. The control loop illustrated in FIG. 11 is configured completely digitally, whereby a simple realisability and low susceptibility to interference are ensured. The bit width conversion by the converter circuit 170 need not necessarily be carried out for this purpose however, since the output signals 9, 10 that are made available by the interconnection and sampling block 161 are already digitally coded.

FIG. 12 shows the time progression of signals of the master delay control loop 100, 100′ in the delay regulation. A reset signal 22, the second clock signal 2, the frequency-halved second clock signal 2″, the first clock signal 1, the input clock selection signal 24, an activation signal 21, the digital control signal 15, the delayed clock signal 28 with its subsignals, the status signal 14 and a freeze signal 23 are all shown.

The master delay control loop 100, 100′ is activated by first of all setting the activation signal 21 at a high signal level. The adjustment procedure of the master delay control loop 100, 100′ starts at the point in time at which the reset signal 22 is likewise set at a high signal level. The first clock signal 1 is selected as input signal of the master delay control loop 100, 100′ by means of the input clock selection signal 24. The digital control signal 15 has at this point in time a digital value that is indicated diagrammatically by the letter X_{b} within the “eyes” of the digital control signal 15.

The adjustment of the master delay control loop 100, 100′ takes place during a first time span T_{aq}. During this phase the digital control signal 15 assumes a value that makes available the previously-explained fixed phase relationship between the delayed clock signal 28 and the input clock signal 1. After the time span T_{aq} the value of the digital control signal 15 fluctuates only slightly about a fixed value. If this state is maintained for a predetermined time, the status signal 14 is set from a low signal level to a high signal level, in order thereby to indicate the locked state of the master delay control loop 100, 100′. After a further predetermined time span T_{fr} has elapsed, the freeze signal is then set from a high signal level to a low signal level, whereby the further regulation of the master delay control loop 100, 100′ is suspended and the value assumed last by the digital control signal 15 is retained. By means of this “freezing” of the master delay control loop 100, 100′ energy can be saved in the stably adjusted state of the master delay control loop 100, 100′ since unnecessary regulating procedures are avoided.

The predetermined time spans Tₗₖ and T_{fr} may be preset depending on the respective requirements.

FIG. 13 shows the time progression of signals for the slave delay control loops 200, 300, 400. The reset signal 22, the second clock signal 2, the frequency-halved second clock signal 2″, the first clock signal 1, the input clock selection signal 31 of the slave delay control loop 200, 300, 400, an activation signal 20 of the slave delay control loop 200, 300, 400, the digital control signal 15, the status signal 14, the derived status signal 14′, a freeze signal 23′ of the slave delay control loop 200, 300, 400, and the phase selection control signal 33, are again shown.

The time span Tₗₖ is in this case shown truncated, since in this time span no relevant procedures for the slave delay control loop 200, 300, 400 take place. The slave delay control loop 200 is activated by setting the activation signal 20 to a high signal level. The adjustment procedure begins again with the setting of the reset signal 22 to a high signal level. The input clock pulse signal to be delayed by the slave delay control loop 200, 300, 400 is selected by the input clock selection signal 31.

As has already been explained, when the master delay control loop 100, 100′ is locked, after a predetermined time span Tₗₖ the status signal 14 from the master delay control loop 100, 100′ is set to a high signal level. At this point in time also the slave delay control loop 200, 300, 400 is thus adjusted to a specific phase relationship of the delayed signals with respect to the first clock signal. A predetermined time span Tᵥₐ after the setting of the status signal 14 to a high signal level, a further status signal 14′ is set from a high signal level to a low signal level in order to indicate thereby that the slave delay control loop 200, 300, 400 is in a valid operating state. At a further predetermined time span T_{fr,s} after indicating of the valid operating state of the slave delay control loop 200, 300, 400, as already explained above for the master delay control loop 100, 100′ the slave delay control loop 200, 300, 400 is decoupled from the regulation by setting the freeze signal 23′ from a high signal level to a low signal level, wherein the previous digital control signal 15 is maintained. A specific additional time span T_{ad} after indicating of the valid operating mode by the status signal 14′ or after “freezing” of the slave delay control loop 200, 300, 400, the desired phase relation of the output clock signal 3a, 3b, 3c, 7, 8 of the slave delay control loop 200, 300, 400 is adjusted by the phase selection control signal 33.

FIG. 14 shows the time progressions of control clock signals and memory data signals and sampling signals in writing and reading procedures of the memory. Here FIG. 14(a) refers to a writing procedure and FIG. 14(b) refers to a reading procedure, in which in each case the time progressions at the output of the memory interface are shown. In particular with memories that can be read at a high data rate, e.g. DDR memories, it is necessary to delay the aforementioned signal in such a way that the desired phase relationship between the clock, sampling and memory data signals exists at the memory site.

FIG. 14(a) refers to a writing procedure. The control clock signal 7, 8 of the command and address block of FIG. 2, as well as the output clock signal 3b for the memory data signals 4 and the output clock signal 3a for the sampling signal 3′ are shown here. The output clock signal 3a has basically a phase shift of 900 with respect to the output clock signal 3b. In order to be able to make available at the memory site the desired phase relationship between the output clock signals 7, 8 of the command and address block and the output clock signals 3a and 3b for the sampling signal 3′ and for the memory data signal 4, the phases of the output clock signals 3a, 3b are shifted. This is accomplished by a coarse adjustment of ±45° phase shift, and a fine adjustment that is equal to ⅛ of the coarse adjustment, i.e. 5.625°.

In the writing procedure the aim is to generate the memory data signal 4 on the basis of the output clock signal 3b in such a way that, at the memory site, edges of the control clock signal 7, 8 of the command and address block coincide in time with edges of the memory data signal 4.

The corresponding signal progressions for a reading procedure are illustrated in FIG. 14(b). In this case it is necessary that the output clock signal 3a for the sampling signal 3′ has a phase shift of 90° with respect to the edges of the memory data signal 4. For this purpose a corresponding delay with respect to the control clock signal 7, 8 of the memory and address block must again be made available. This is again effected by the coarse adjustment of ±45° and the fine adjustment of ⅛, i.e. 5.625° phase shift of the output clock signal 3a. The coarse adjustment of the phase relationship by ±45° is achieved in the slave delay control loops 200, 300, 400 described above by tapping the output clock signal 3a, 3b, 3c, 7, 8 at a corresponding delay stage. For example, a phase displacement of 90° with respect to the input clock signal would be made available, in which the output clock signal is tapped at the output of the delay stage at which also the subsignal 28″ of the delayed clock signal of the master delay control loop 100, 100′ is tapped. A 45° smaller phase shift is achieved by a tapping of the output clock signal that corresponds to the subsignal 28′ of the delayed clock signal 28 of the master delay control loop 100, 100′. An output clock signal with a 45° larger phase shift is achieved by a tapping that corresponds to the tapping of the subsignal 28″′ of the delayed clock signal 28 of the master delay control loop 100, 100′.

The fine adjustment in steps of 5.625° is achieved by interpolation of the delayed signals from two possible settings for the coarse selection of the phase relationship.

If the delay stages that correspond to the subsignals with 45°, 90° and 135° phase shift have a plurality of delay elements 115, 215, the fine adjustment is also possible by selecting output signals of the individual delay elements 115, 215.

Although in FIG. 14 only a phase displacement of the output clock signal 3a and 3b has been indicated, each of the output clock signals 3a, 3b, 3c or also 7, 8 can as required be matched separately in their phase relation by means of the various slave delay control loops 200, 300, 400.

FIG. 15 illustrates in a circular diagram the selection of the desired phase relation of the output clock signals 3a, 3b, 3c, 7, 8 by the phase selection control signal 33. A coarse selection of the phase relation of the output clock signal is carried out in steps of 45° by selecting a quadrant. A first quadrant is identified by I and extends between phase angles of −45° and +45°. In this connection 0° would correspond to the reference clock signal to which the phase angles refer. As a rule this is the first clock signal 1. A phase angle of 180° would in turn correspond to the inverted reference clock signal. A second quadrant is identified by II and extends between 45° and 135°. A third quadrant is identified by III and extends between 135° and 225°. A fourth quadrant is identified by IV and extends between 225° and 315°. The whole circular diagram is thus covered by the quadrants I-IV.

FIG. 15(b) illustrates in a table the selection of phase angles from the circular diagram illustrated in FIG. 15(a), by means of the phase selection control signal 33. For this purpose the phase selection control signal 33 comprises a first section A of two bits, which determines the quadrant in which the phase angle to be selected is located. The bit combinations for sub signals 33e and 33f of the phase selection control signal 33 that determine the quadrant are shown in section A of the table. The phase selection control signal 33 comprises a further section B of four bits, by means of which the exact phase angle is determined within the quadrant specified in section A. There are thus sixteen possible phase angles for each quadrant, which corresponds to the already explained fine adjustment of the phase angle in steps of 5.625°. If a number N is coded by the section B of the phase selection control signal 33, the value of the phase angle is obtained from the beginning of the quadrant plus N times 5.625°.

This fine adjustment is less than 0.1 ns with currently conventional clock rates of DDR memories.

With the aforedescribed device for the regulated delay of clock signals it is possible to cover the whole circular diagram illustrated in FIG. 15(a) with adjustable phase relationships. It is therefore not necessary for the delay chain 110 of the master delay control loop 100, 100′ or for the delay chain 210 of the slave delay control loops 200, 300, 400 to make available delayed signals of more than 135° phase shift with respect to the reference clock signal, since delayed clock signals with a larger phase shift can be generated by inverting the delayed clock signals with 45°, 90° and 135°, as well as by inverting the non-delayed reference clock signal.

Although it has been assumed in the preceding discussion that the output clock signals 3a, 3b, 3c, 7, 8 are always generated by slave delay control loops 200, 300, 400, it is obviously also possible to tap output clock signals at the master delay control loop 100, 100′. Furthermore, it is not absolutely necessary that the first clock signal 1 is delayed in the master delay control loop 100, 100′, and also used as reference clock signal for the phase comparison in the phase detector 160. Alternatively it would be possible for the reference clock signal to be a further clock signal that has the same frequency as the first clock signal.

1-22. (canceled)

23. A device for the regulated delay of a clock signal comprising:
at least one delay element configured to delay the clock signal by a specific time contribution in order to generate a delayed clock signal; and
a phase detector operable to compare the phase of the delayed clock signal with a reference clock signal, the phase detector operable to generate a comparison signal depending on the comparison of the delayed clock signal with the reference clock signal;
wherein the at least one delay element is configured to determine the time by which the clock signal is delayed depending on a control signal derived from the comparison signal;
wherein a further clock signal that is generated independently of the clock signal and reference clock signal is fed to the phase detector, and
wherein the phase detector is configured to generate the comparison signal as a digital signal comprising a sequence of pulses, in which the pulse duty ratio and/or the frequency of the comparison signal is determined depending on the further clock signal.

24. The device according to claim 23 wherein the reference clock signal is derived from the clock signal.

25. The device according to claim 23 wherein the reference clock signal is formed by the clock signal.

26. The device according to claim 23 wherein the further clock signal is generated by a phase-locked loop.

27. The device according to claim 23 wherein the further clock signal has twice the frequency of the clock signal.

28. The device according to claim 23 wherein the device comprises a frequency multiplier operable to generate the further clock signal from a second clock signal that is generated independent of the clock signal and that has the same frequency as the clock signal.

29. The device according to claim 23 wherein the phase detector comprises (i) at least one interconnection member to which the delayed clock signal and the reference clock signal are fed, wherein an output signal of the interconnection member is determined by the relative delay of the delayed clock signal with respect to the reference clock signal, and (ii) at least one sampling member configured to sample an output signal of the interconnection member in a manner controlled by the further clock signal.

30. The device according to claim 29 wherein the interconnection member is configured to generate an output signal as a pulse-width modulated signal, and wherein the sampling member comprises at least one first flip-flop element having an input that is supplied with the pulse-width modulated signal, and at least one second flip-flop element having an input that is supplied with an output signal of the at least one first flip-flop element, wherein the at least one first flip-flop element changes its state depending on the value of the further clock signal and the at least one second flip-flop element changes its state at an edge of the further clock signal.

31. The device according to claim 23 wherein the at least one delay element comprise a plurality of delay elements forming a plurality of delay stages connected in series, each of the plurality of delay stages including a delay stage input that receives a delay stage input signal and a delay stage output, wherein a correspondingly delayed clock signal can be tapped at each of the delay stage outputs.

32. The device according to claim 31 wherein each of the plurality of delay stages delays its delay stage input signal by an identical time contribution.

33. The device according to claim 31 wherein the delayed clock signal is fed to the phase detector in the form of a plurality of subsignals respectively tapped at the delay stage output of one of the delay stages.

34. The device according to claim 33 wherein the phase detector comprises (i) at least one interconnection member to which the delayed clock signal and the reference clock signal are fed, wherein an output signal of the interconnection member is determined by the relative delay of the delayed clock signal with respect to the reference clock signal, and (ii) at least one sampling member configured to sample an output signal of the interconnection member in a manner controlled by the further clock signal, and wherein the at least one interconnection member includes at least one AND interconnection member, wherein inputs of the AND interconnection member are supplied with the reference clock signal or with the inverted reference clock signal, and with the subsignals of the delayed clock signal.

35. The device according to claim 34 wherein the delayed clock signal comprises 2n+1 subsignals, where n=1, 2, 3, . . . , an nth subsignal being delayed with respect to the reference clock signal by an n-fold value of the delay of a delay stage, and wherein the at least one interconnection member comprises a first and a second AND interconnection member, the inputs of the first AND interconnection member being supplied with the reference clock signal and with the first to the (n+1)th subsignal of the delayed clock signal, and the inputs of the second AND interconnection member are supplied with the inverted reference clock signal and with the (n+1)th to the (2n+1)th subsignal of the delayed clock signal.

36. The device according to claim 23 wherein the device comprises further delay elements that are driven by the control signal.

37. The device according to claim 36 wherein the further delay elements are configured identically to the at least one delay element.

38. The device according to claim 37 wherein the further delay elements comprise a plurality of delay stages arranged in series, wherein a correspondingly delayed clock signal can be tapped at the output of each of the delay stages.

39. The device according to claim 38 wherein the device is configured to generate a delayed output clock signal that is derived from at least one of the delayed clock signals that can be tapped at the delay stages of the further delay elements.

40. The device according to claim 39, wherein the device further comprises a multiplexer, and wherein a phase relationship between the reference clock signal and the delayed output clock signal can be adjusted by controlling the multiplexer so as to select the delayed clock signals that can be tapped at the delay stages of the further delay elements.

41. The device according to claim 39, wherein the device further comprises and interpolation member, and wherein the device is configured so as to generate the delayed output clock signal by interpolation of at least two of the delayed clock signals that can be tapped at the delay stages of the further delay elements.

42. The device according to claim 23 wherein the device is configured for use in the generation and synchronization of control clock signals, data signals and sampling signals for memory devices.

43. An arrangement comprising:
a memory; and
a device for the regulated delay of a clock signal interfacing with the memory, the device for the regulated delay of a clock signal comprising
at least one delay element configured to delay the clock signal by a specific time contribution in order to generate a delayed clock signal; and
a phase detector operable to compare the phase of the delayed clock signal with a reference clock signal, the phase detector operable to generate a comparison signal depending on the comparison of the delayed clock signal with the reference clock signal;
wherein the at least one delay element is configured to determine the time by which the clock signal is delayed depending on a control signal derived from the comparison signal;
wherein a further clock signal that is generated independently of the clock signal and reference clock signal is fed to the phase detector, and
wherein the phase detector is configured to generate the comparison signal as a digital signal comprising a sequence of pulses, in which the pulse duty ratio and/or the frequency of the comparison signal is determined depending on the further clock signal.

44. A method of generating and synchronizing control clock signals, data signals and sampling signals for a memory device, the method comprising:
a) providing at least one delay element operable to delay a clock signal by a specific time contribution in order to generate a delayed clock signal;
b) providing a phase detector operable to compare the phase of the delayed clock signal with a reference clock signal; and
c) generating a comparison signal depending on the comparison of the delayed clock signal with the reference clock signal;
d) determining the time by which the clock signal is delayed depending on a control signal derived from the comparison signal; and
e) feeding a further clock signal that is generated independently of the clock signal and the reference clock signal to the phase detector;
wherein the comparison signal is generated as a digital signal comprising a sequence of pulses, in which the pulse duty ratio and/or the frequency of the comparison signal is determined depending on the further clock signal.
